(19) United States
(12) Patent Application Publication
(10) Pub. No.: US 2026/0198007 A1
(43) Pub. Date: Jul. 9, 2026

(54) MEMORY DEVICE AND MANUFACTURING METHOD OF THE MEMORY DEVICE

(71) Applicant: SK hynix Inc., Icheon-si Gyeonggi-do (KR)

(72) Inventors: Won Geun CHOI, Icheon-si Gyeonggi-do (KR); Jung Shik JANG, Icheon-si Gyeonggi-do (KR); Rho Gyu KWAK, Icheon-si Gyeonggi-do (KR); Mi Seong PARK, Icheon-si Gyeonggi-do (KR); In Su PARK, Icheon-si Gyeonggi-do (KR); Na Yeong YANG, Icheon-si Gyeonggi-do (KR); Seok Min CHOI, Icheon-si Gyeonggi-do (KR)

(73) Assignee: SK hynix Inc., Icheon-si Gyeonggi-do (KR)

(21) Appl. No.: 19/209,307

(22) Filed: May 15, 2025

(30) Foreign Application Priority Data
Jan. 3, 2025 (KR) 10-2025-0000709

(51) Int. Cl. H10B 43/27; H10B 43/10; H10B 43/35

(52) U.S. Cl. CPC H10B 43/27; H10B 43/10; H10B 43/35

(57) ABSTRACT

A method of manufacturing a memory device includes forming a cell opening penetrating through a stack structure, forming a cell plug in the cell opening, and forming a preliminary opening penetrating at least a portion of the stack structure. The method also includes expanding the preliminary opening to form an expanded opening having a greater width than the preliminary opening by removing a portion of the stack structure through the preliminary opening. The method further includes forming a contact opening by extending the expanded opening farther downward by removing a portion of the stack structure through the expanded opening. The method additionally includes forming a contact in the contact opening.

### CROSS-REFERENCE TO RELATED APPLICATION

The present application claims priority under 35 U.S.C. § 119(a) to Korean patent application number 10-2025-0000709 filed on Jan. 3, 2025, in the Korean Intellectual Property Office, the entire disclosure of which application is incorporated herein by reference.

### BACKGROUND

### 1. Technical Field

Various embodiments of the present disclosure generally relate to a memory device and a manufacturing method of the memory device, and more particularly, to a memory device including a memory block having a three-dimensional structure and a method of manufacturing the memory device having a three-dimensional structure.

### 2. Related Art

A non-volatile memory device may retain stored data even when supplied power is interrupted. A non-volatile memory device may have a two-dimensional structure or a three-dimensional structure according to how memory cells are arranged. Memory cells of a non-volatile memory device having a two-dimensional structure may be arranged in a single layer on a substrate, and memory cells of a non-volatile memory device having a three-dimensional structure may be stacked in a vertical direction on the substrate. Because the degree of integration of a non-volatile memory device having a three-dimensional structure is higher than that of a non-volatile memory device having a two-dimensional structure, electronic devices are increasingly being manufactured with non-volatile memory devices having a three-dimensional structure.

### SUMMARY

According to an embodiment of the present disclosure, a method of manufacturing a memory device may include: forming a cell opening penetrating through a stack structure; forming a cell plug in the cell opening; forming a preliminary opening penetrating at least a portion of the stack structure; expanding the preliminary opening to form an expanded opening having a greater width than the preliminary opening by removing a portion of the stack structure through the preliminary opening; forming a contact opening by extending farther downward by removing a portion of the stack structure through the expanded opening; and forming a contact in the contact opening.

### BRIEF DESCRIPTION OF THE DRAWINGS

FIG. 1 a block diagram illustrating a memory device according to an embodiment of the present disclosure;

FIG. 2 is an isometric diagram illustrating a memory device according to an embodiment of the present disclosure;

FIGS. 3A and 3B are plan and cross-sectional diagrams illustrating a memory device including a contact formed according to an embodiment of the present disclosure;

FIGS. 4A to 4L are cross-sectional diagrams illustrating a method of manufacturing contacts having a width greater than a cell plug according to an embodiment of the present disclosure;

FIG. 5 is a diagram illustrating a memory card system to which a memory device of the present disclosure is applied; and

FIG. 6 is a block diagram illustrating a Solid-State Drive (SSD) system to which a memory device of the present disclosure is applied.

### DETAILED DESCRIPTION

Specific structural or functional descriptions disclosed herein are merely illustrative for the purpose of describing embodiments according to the concept of the present disclosure. Embodiments according to the concept of the present disclosure may be implemented in various forms and should not be construed as being limited to the specific embodiments set forth herein.

Hereinafter, embodiments are described with reference to the accompanying drawings for those skilled in the art to be able to implement the technical spirit of the present disclosure.

Various embodiments are directed to a memory device for which a process of manufacturing a word line contact may be simplified, and a method of manufacturing the memory device.

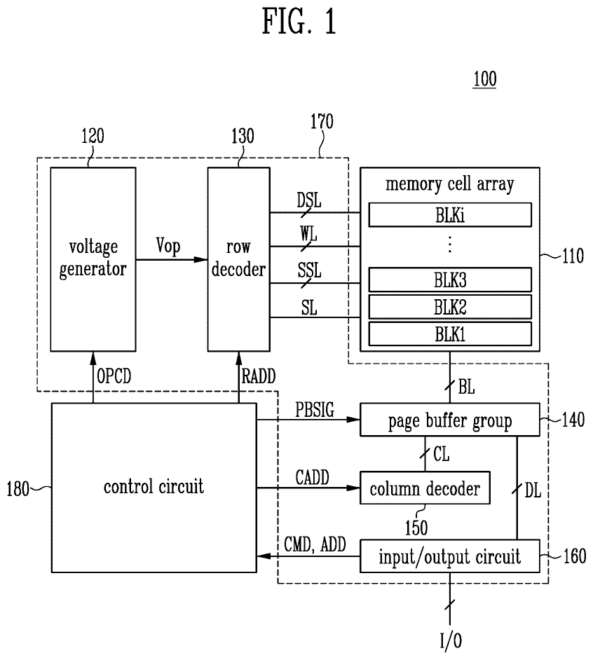

FIG. 1 is a block diagram illustrating a memory device 100 according to an embodiment of the present disclosure.

Referring to FIG. 1, the memory device 100 may include a memory cell array 110, a peripheral circuit 170, and a control circuit 180.

The memory cell array 110 may include first to i-th memory blocks BLK1 to BLKi. Each of the first to i-th memory blocks BLK1 to BLKi may include memory cells capable of storing data. Drain select lines DSL, word lines WL, source select lines SSL, and a source line SL may be connected to each of the first to i-th memory blocks BLK1 to BLKi, and bit lines BL may be connected in common to the first to i-th memory blocks BLK1 to BLKi. The word lines WL may be connected to a row decoder 130 via word line contacts.

The first to i-th memory blocks BLK1 to BLKi may have a three-dimensional structure. Memory blocks having a three-dimensional structure may include memory cells stacked in a vertical or normal direction on a substrate.

The memory cells may store one, two, or more bits of data according to a program method. For example, a method in which one bit of data is stored in one memory cell is referred to as a single-level cell method, and a method in which two bits of data are stored is referred to as multi-level cell method. A method in which three bits of data are stored in one memory cell is referred to as a triple-level cell method, and a method in which four bits of data are stored is referred to as a quad-level cell method. In addition, five or more bits of data may be stored in one memory cell.

The peripheral circuit 170 may be configured to perform a program operation to store data in the memory cell array 110, a read operation to output data stored in the memory cell array 110, and an erase operation to erase data stored in the memory cell array 110. The peripheral circuit 170 may include a voltage generator 120, the row decoder 130, a page buffer group 140, a column decoder 150, and an input/output circuit 160.

The voltage generator 120 may generate various operating voltages Vop used for the program operation, the read operation, or the erase operation in response to an operation code OPCD. For example, the voltage generator 120 may be configured to generate program voltages, turn-on voltages, turn-off voltages, negative voltages, precharge voltages, verify voltages, read voltages, pass voltages, or erase voltages in response to the operation code OPCD. The operating voltages Vop generated at the voltage generator 120 may be applied to the drain select lines DSL, the word lines WL, the source select lines SSL, and the source line SL of a selected memory block via the row decoder 130.

The program voltages may be applied to a selected word line of the word lines WL in a program operation, and may be used to increase a threshold voltage of memory cells connected to the selected word line. The turn-on voltages may be applied to the drain select lines DSL or the source select lines SSL and may be used to turn on drain select transistors or source select transistors. The turn-off voltages may be applied to the drain select lines DSL or the source select lines SSL and may be used to turn off the drain select transistors or the source select transistors. For example, the turn-off voltage may be set to 0 V. The precharge voltages may be higher than 0 V and may be applied to the bit lines in a read operation. The verify voltages may be used during the verify operation to determine whether the threshold voltage of the selected memory cells has risen to a target level. The verify voltages may be set at various levels depending on the target level and may be applied to the selected word line.

The read voltages may be applied to the selected word line during the read operation of the selected memory cells. For example, the read voltages may be set to various levels depending on a program method of the selected memory cells. The pass voltages may be applied to unselected ones of the word lines WL during the program or read operation, which may be used to turn on memory cells connected to the unselected word lines. The erase voltages may be used in the erase operation to erase memory cells included in the selected memory block and may be applied to the source line SL.

The row decoder 130 may transmit the operating voltages Vop to the drain select lines DSL, the word lines WL, the source select lines SSL, and the source line SL connected to the selected memory block according to a row address RADD. For example, the row decoder 130 may be connected to the voltage generator 120 via global lines, and may be connected to the first to i-th memory blocks BLK1 to BLKi via the drain select lines DSL, the word lines WL, the source select lines SSL, and the source line SL.

The page buffer group 140 may include page buffers (not shown) connected to the first to i-th memory blocks BLK1 to BLKi, respectively. Each of the page buffers may be connected to the first to i-th memory blocks BLK1 to BLKi via the bit lines BL. In a read operation, the page buffers may sense, in response to page buffer control signals PBSIG, a current or voltage of bit lines which varies according to the threshold voltage of the selected memory cells, and temporarily store the sensed data.

The column decoder 150 may transmit data between the page buffer group 140 and the input/output circuit 160 in response to a column address CADD. For example, the column decoder 150 may be connected to the page buffer group 140 via column lines CL and may transmit enable signals via the column lines CL. The page buffers included in the page buffer group 140 may receive or output data via data lines DL in response to the enable signals.

The input/output circuit 160 may receive or output a command CMD, an address ADD, or data via input/output lines I/O. For example, the input/output circuit 160 may transmit the command CMD and the address ADD received from an external controller via the input/output lines I/O to the control circuit 180, and it may transmit the data received from the external controller via the input/output lines I/O to the page buffer group 140. Alternatively, the input/output circuit 160 may output data received from the page buffer group 140 to the external controller through the input/output lines I/O.

The control circuit 180 may output at least one of the operation code OPCD, the row address RADD, the page buffer control signals PBSIG, or the column address CADD in response to the command CMD and the address ADD. For example, when the command CMD input to the control circuit 180 corresponds to a program operation, the control circuit 180 may control the peripheral circuit 170 so that the program operation of the memory block selected by the address ADD is performed. When the command CMD input to the control circuit 180 corresponds to a read operation, the control circuit 180 may control the peripheral circuit 170 to perform the read operation of the memory block selected by the address ADD and output the read data. When the command CMD input to the control circuit 180 corresponds to an erase operation, the control circuit 180 may control the peripheral circuit 170 to perform the erase operation of the selected memory block.

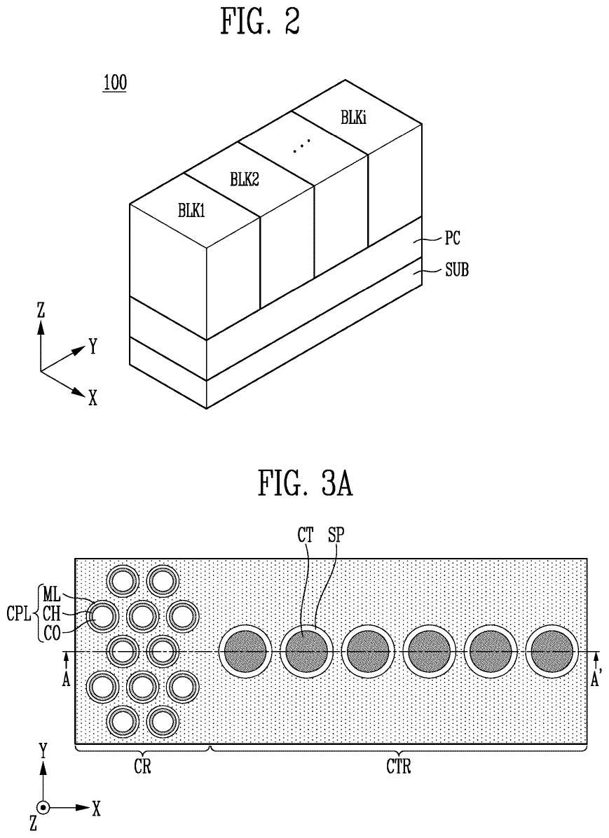

FIG. 2 is an isometric diagram illustrating the memory device 100 according to an embodiment of the present disclosure.

Referring to FIG. 2, the memory device 100 may include a peripheral circuit structure PC and the memory blocks BLK1 to BLKi located over a substrate SUB. The memory blocks BLK1 to BLKi may overlap the peripheral circuit structure PC.

The substrate SUB may be a single crystal semiconductor layer. For example, the substrate SUB may be a bulk silicon substrate, a silicon-on-insulator substrate, a germanium substrate, a germanium-on-insulator substrate, a silicon-germanium substrate, or an epitaxial thin film formed by a selective epitaxial growth method.

The peripheral circuit structure PC may include the row decoder 130, the column decoder 150, the page buffer group 140, the control circuit 180, and the like which constitute a circuit for controlling operations of the memory blocks BLK1 to BLKi. For example, the peripheral circuit structure PC may include one or more NMOS transistors, PMOS transistors, resistors, capacitors, and the like electrically connected to the memory blocks BLK1 to BLKi. The peripheral circuit structure PC may be located between the substrate SUB and the memory blocks BLK1 to BLKi.

Each of the memory blocks BLK1 to BLKi may include a source structure, bit lines, cell strings electrically connected to the source structure and the bit lines, word lines electrically connected to the cell strings, and select lines electrically connected to the cell strings. Each of the cell strings may include memory cells and select transistors connected in series by a cell plug. Each of the select lines may be used as a gate electrode of a corresponding select transistor, and each of the word lines may be used as a gate electrode of a corresponding memory cell. The memory blocks BLK1 to BLKi may include word line contacts which contact the word lines, respectively.

As the height of the memory blocks BLK1 to BLKi in a Z direction increases, a multi-stack method of stacking two or more stack structures may be used. For example, each of the memory blocks BLK1 to BLKi may include a first stack structure and a second stack structure on the first stack structure, and each of the cell plugs included in the memory blocks BLK1 to BLKi may include a first portion in the first stack structure and a second portion in the second stack structure. For another example, each of the memory blocks BLK1 to BLKi may include a first stack structure, a second stack structure, and a third stack structure stacked in the Z direction, and each of the cell plugs included in the memory blocks BLK1 to BLKi may include a first portion in the first stack structure, a second portion in the second stack structure, and a third portion in the third stack structure.

In another embodiment, the substrate SUB, the peripheral circuit structure PC, and the memory blocks BLK1 to BLKi may be stacked in a reverse order to the order shown in FIG. 2. For example, the peripheral circuit structure PC may be located over the memory blocks BLK1 to BLKi.

In another embodiment, unlike the embodiment shown in FIG. 2, the peripheral circuit structure PC may be located in an area of the substrate SUB which does not overlap the memory blocks BLK1 to BLKi. For example, the peripheral circuit structure PC and the memory blocks BLK1 to BLKi may be respectively located in separate non-overlapping areas on the substrate SUB.

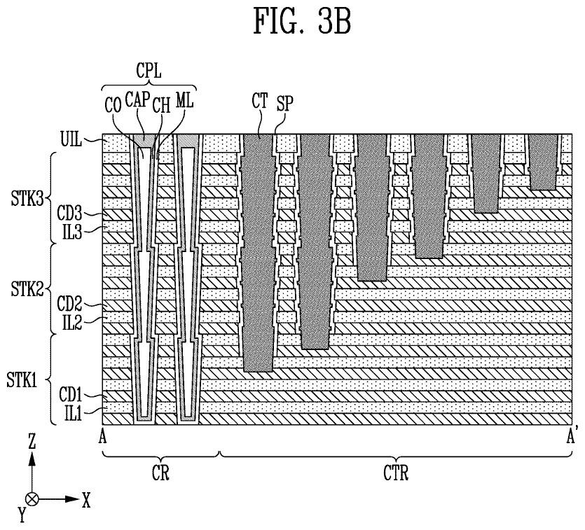

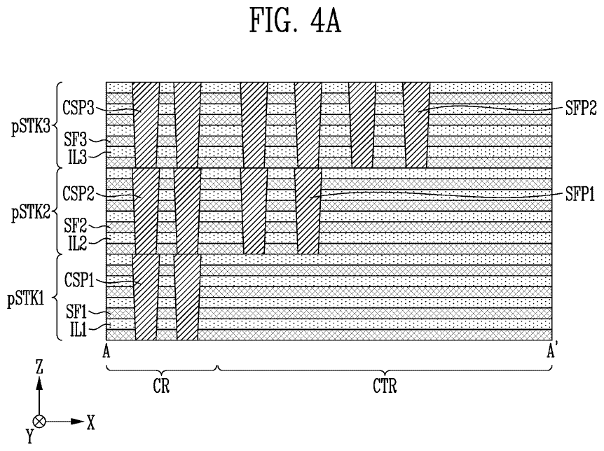

FIGS. 3A and 3B are diagrams illustrating the memory device 100 including a contact CT formed according to an embodiment of the present disclosure. FIG. 3A is a plan view of a layout of the memory device 100 according to an embodiment of the present disclosure. FIG. 3B is a cross-sectional view taken along line A-A′ of FIG. 3A.

Referring to FIG. 3A, a cell region CR and a contact region CTR may be defined for the memory device 100 (e.g., one of the memory blocks BLK1 to BLKi of FIG. 2). The contact region CTR may be located in an X direction with respect to the cell region CR. The contact region CTR may extend in the X direction from the cell region CR. In another embodiment, unlike the embodiment shown in FIG. 3A, the contact region CTR may extend in a Y direction from the cell region CR, or it may extend in the X direction and in the Y direction. In other embodiments, the cell region CR and the contact region CTR may be arranged in various ways.

Cell plugs CPL may be located in the cell region CR. The cell plugs CPL may be arranged in the X-Y plane. The cell plugs CPL may be spaced apart from each other in the X and Y directions. Each of the cell plugs CPL may extend in the Z direction. Each of the cell plugs CPL may be electrically connected to a bit line (e.g., one of the bit lines BL of FIG. 1) and a source line (e.g., the source line SL of FIG. 1) via a wiring structure.

Each of the cell plugs CPL may include a memory layer ML, a channel layer CH, and a core pillar CO. The memory layer ML may have a tubular shape. The memory layer ML may surround the channel layer CH. Although not shown, the memory layer ML may include a blocking layer, a charge trap layer, and a tunneling layer. The channel layer CH may be formed along an inner surface of the memory layer ML. The core pillar CO may fill in the channel layer CH. The core pillar CO may have a cylindrical shape surrounded by the channel layer CH. Although not shown, each of the cell plugs CPL may further include a capping layer connected to the channel layer CH on the core pillar CO.

The blocking layer and the tunneling layer included in the memory layer ML may include an oxide layer (e.g., a silicon oxide layer), an oxynitride layer (e.g., a silicon oxynitride layer), or a combination thereof. The charge trap layer included in the memory layer ML may include a nitride layer or a variable resistance material. The channel layer CH and the capping layer may include an undoped silicon layer or a doped silicon layer. The core pillar CO may include an insulating layer (e.g., an oxide layer) or a conductive layer.

The contacts CT may be located in the contact region CTR. A plurality of contacts may be arranged in the contact region CTR. FIG. 3A shows only six contacts CT, however, more than six contacts CT may be arranged in the contact region CTR. The contacts CT may be spaced apart from one another in the X direction. The contacts CT may be arranged in the X direction. In addition, the contacts CT may be arranged in various ways in the contact region CTR. For example, the contacts CT might not be arranged side by side in the X direction, but may instead be arranged in a zigzag. Each of the contacts CT may extend in the Z direction. The contacts CT may include a conductive material. The contacts CT may also be referred to as word line contacts or contact plugs.

Spacers SP may surround the contacts CT, respectively. The spacer SP may contact a side surface of the contact CT. The contacts CT may each fill in the spacer SP. The spacers SP may include an insulating layer. For example, the spacers SP may include an oxide layer.

Referring to FIG. 3B, the memory device 100 may include a first stack structure STK1, a second stack structure STK2, and a third stack structure STK3. The second stack structure STK2 may be arranged over the first stack structure STK1. The second stack structure STK2 may be located in the Z direction with respect to the first stack structure STK1. The third stack structure STK3 may be arranged over the second stack structure STK2. The third stack structure STK3 may be located in the Z direction with respect to the second stack structure STK2. An upper surface of the first stack structure STK1 may be in contact with a lower surface of the second stack structure STK2. An upper surface of the second stack structure STK2 may be in contact with a lower surface of the third stack structure STK3. The first to third stack structures STK1 to STK3 may extend from the cell region CR to the contact region CTR. The first to third stack structures STK1 to STK3 may be located in the cell region CR and in the contact region CTR. An upper insulating layer UIL may be located over the third stack structure STK3. The first to third stack structures STK1 to STK3 may also be referred to as first to third sub-stack structures, respectively, and the entire structure including the first to third stack structures STK1 to STK3 and the upper insulating layer UIL may be referred to as a stack structure.

The first stack structure STK1 may include first conductive layers CD1 and first interlayer insulating layers IL1. The first conductive layers CD1 and the first interlayer insulating layers IL1 may be alternately stacked in the Z direction. The second stack structure STK2 may include second conductive layers CD2 and second interlayer insulating layers IL2. The second conductive layers CD2 and the second interlayer insulating layers IL2 may be alternately stacked in the Z direction. The third stack structure STK3 may include third conductive layers CD3 and third interlayer insulating layers IL3. The third conductive layers CD3 and the third interlayer insulating layers IL3 may be alternately stacked in the Z direction. The first to third conductive layers CD1 to CD3 may include at least one of tungsten (W), cobalt (Co), nickel (Ni), molybdenum (Mo), silicon (Si), or polysilicon (poly-Si). The first to third conductive layers CD1 to CD3 may include the same material as each other. The first to third conductive layers CD1 to CD3 may correspond to gate lines (e.g., the drain select lines DSL, the word lines WL, and the source select lines SSL in FIG. 1). The first to third interlayer insulating layers IL1 to IL3 may include an oxide layer (e.g., a silicon oxide layer). The first to third interlayer insulating layers IL1 to IL3 may include the same material as each other. The upper insulating layer UIL may include a material equivalent to the first to third interlayer insulating layers IL1 to IL3. The upper insulating layer UIL may include an oxide.

The cell plugs CPL may penetrate through the first to third stack structures STK1 to STK3 in the cell region CR. Each of the cell plugs CPL may include the memory layer ML, the channel layer CH, a capping layer CAP, and the core pillar CO. The capping layer CAP may correspond to the capping layer described in relation to FIG. 3A. Memory cells and select transistors may be formed at intersections of the cell plugs CPL and the first to third conductive layers CD1 to CD3. The cell plugs CPL may be used as a channel region of a cell string. The width of each of the cell plugs CPL may vary at the interface between the first stack structure STK1 and the second stack structure STK2 and the interface between the second stack structure STK2 and the third stack structure STK3. For example, the width in the X direction of the cell plug CPL at a lower end of the second stack structure STK2 may be less than the width in the X direction of the cell plug CPL at an upper end of the first stack structure STK1.

The contacts CT may extend in the Z direction in the contact region CTR. The contacts CT may extend in the Z direction from one of the first to third conductive layers CD1 to CD3. A lower surface of each of the contacts CT may be in contact with one of the first to third conductive layers CD1 to CD3. The contacts CT may be electrically connected to the first to third conductive layers CD1 to CD3, respectively. For example, each contact CT may extend from the top of the stack structure down to contact a different one of the first to third conductive layers CD1 to CD3.

The side surface of each of the contacts CT may include a concavo-convex structure in that the side surface of the contact CT may include protrusions and recesses. For example, the contacts CT may protrude at levels corresponding to the first to third conductive layers CD1 to CD3 and may be concave at levels corresponding to the first to third interlayer insulating layers IL1 to IL3. However, the specific shape of the concavo-convex structure formed on the side surface of each of the contacts CT (e.g., the protruding position, the length of the protrusion, or the like) does not limit the scope of the present disclosure.

In an embodiment, each of the contacts CT may have a greater width than each of the cell plugs CPL. The diameter of each of the contacts CT may be greater than the diameter of each of the cell plugs CPL. For example, at a particular level, the width in the X direction of each of the contacts CT may be greater than the width in the X direction of each of the cell plugs CPL. Also, at a particular level, the width in the Y direction of each of the contacts CT may be greater than the width in the Y direction of each of the cell plugs CPL.

In another embodiment, each of the contacts CT may have a smaller width than each of the cell plugs CPL. The diameter of each of the contacts CT may be smaller than the diameter of each of the cell plugs CPL. For example, at a particular level, the width in the X direction of each of the contacts CT may be less than the width in the X direction of each of the cell plugs CPL. Also, at a particular level, the width in the Y direction of each of the contacts CT may be less than the width in the Y direction of each of the cell plugs CPL.

The spacers SP may surround the side surfaces of the contacts CT, respectively. The spacers SP may extend along irregularities formed on the side surfaces of the contacts CT. The spacers SP may insulate each contact CT from conductive layers (e.g., the conductive layers CD1 and CD2) other than the conductive layer the contact CT is electrically connected to.

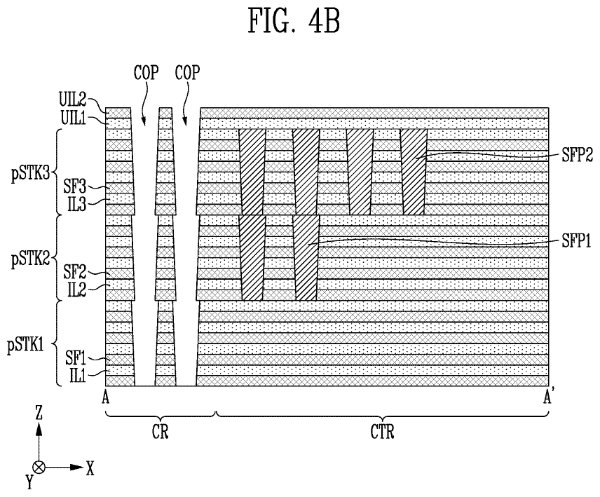

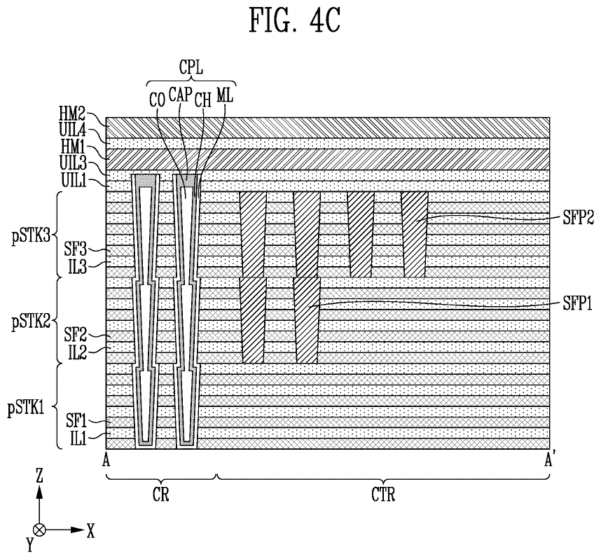

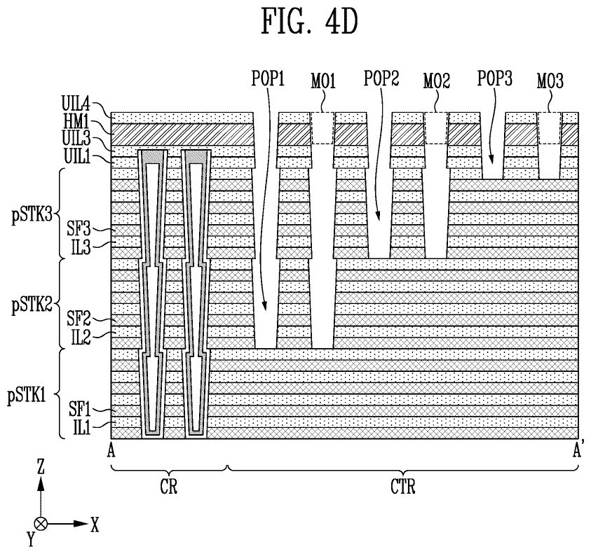

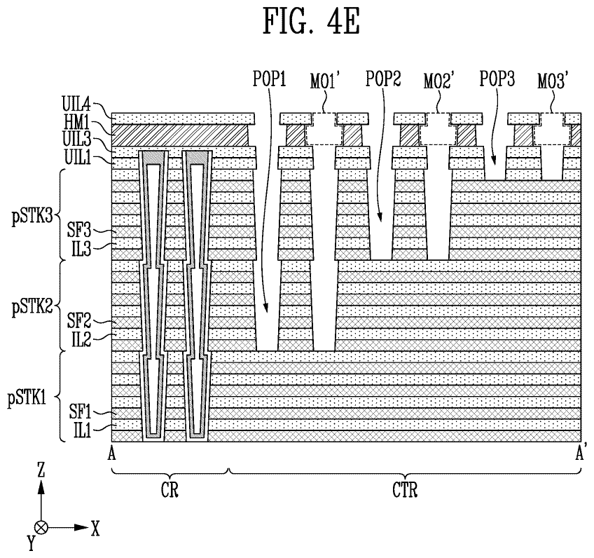

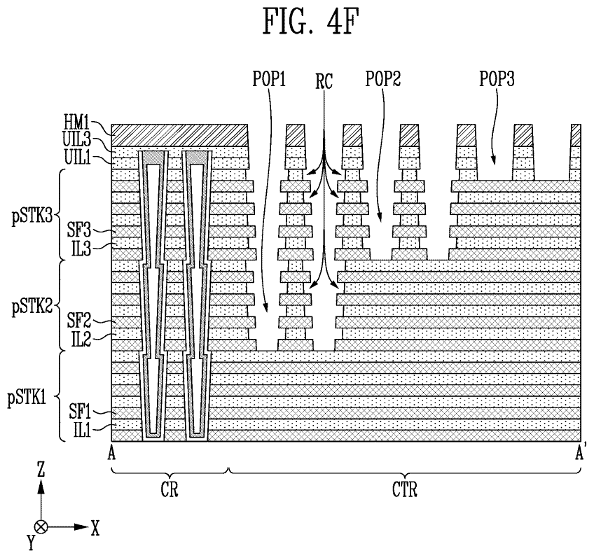

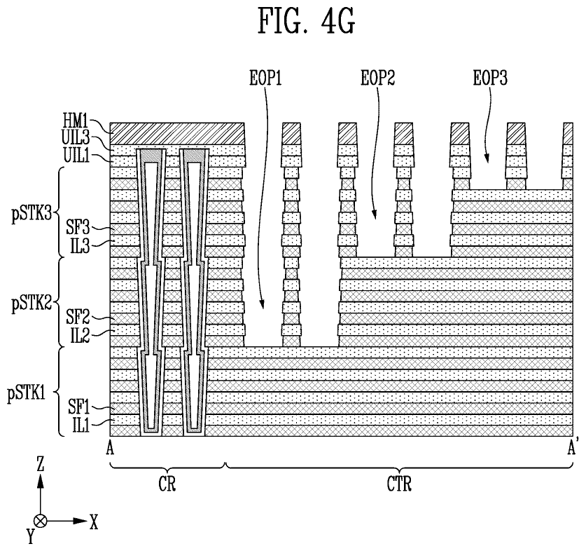

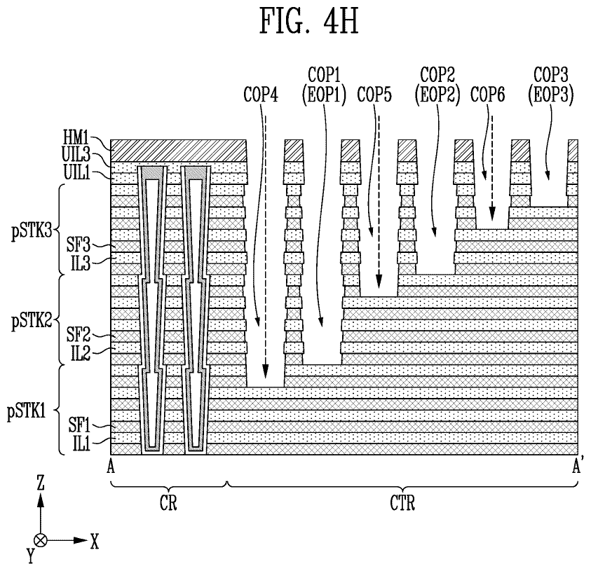

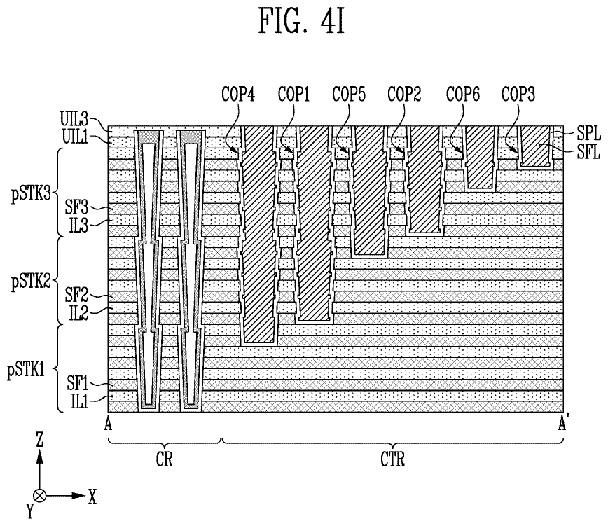

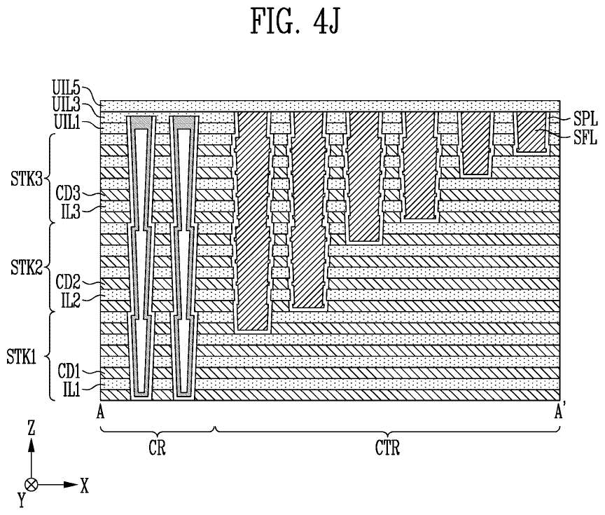

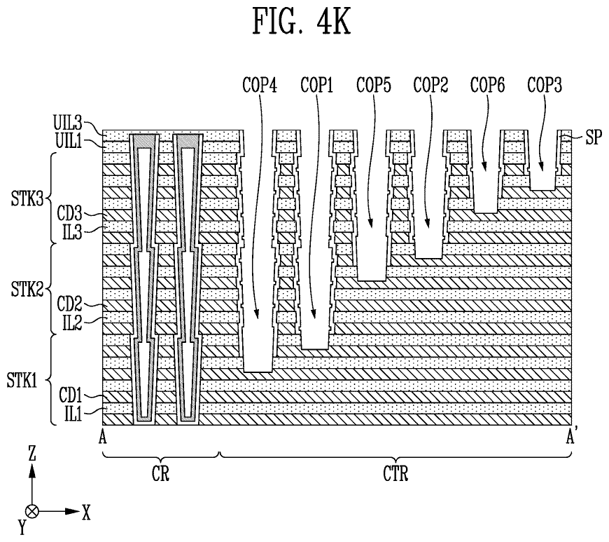

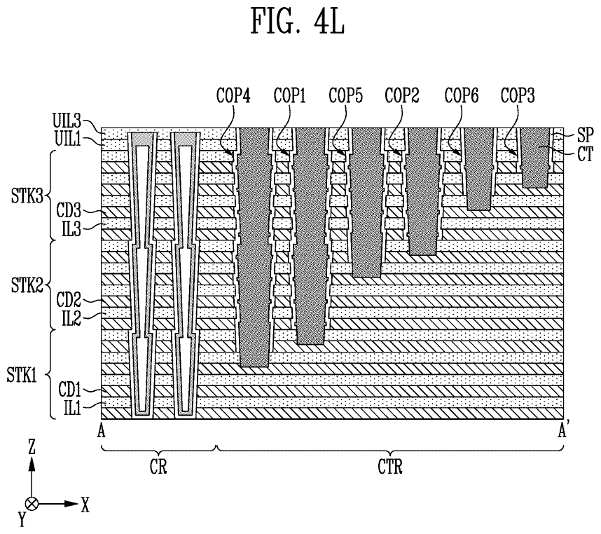

FIGS. 4A to 4L are diagrams illustrating a method of manufacturing contacts having a width greater than a cell plug according to an embodiment of the present disclosure. FIGS. 4A to 4L each show a cross-sectional view corresponding to the cross-section taken along line A-A′ of FIG. 3A at different stages of manufacturing.

Referring to FIG. 4A, a first preliminary stack structure pSTK1 including alternately stacked first interlayer insulating layers IL1 and first sacrificial layers SF1 may be formed. The first interlayer insulating layers IL1 and the first sacrificial layers SF1 may be stacked on each other in the Z direction. The first interlayer insulating layers IL1 may include an insulating material. For example, the first interlayer insulating layers IL1 may include oxide layers (e.g., silicon oxide layers). The first sacrificial layers SF1 may include a material which may be selectively removed in a subsequent process. The first sacrificial layers SF1 may include a material having an etch selectivity different from that of the first interlayer insulating layers IL1. For example, the first sacrificial layers SF1 may include nitride layers.

Subsequently, first cell sacrificial pillars CSP1 may be formed which penetrate through the first preliminary stack structure pSTK1. The first cell sacrificial pillars CSP1 may be formed in the cell region CR. Each of the first cell sacrificial pillars CSP1 may extend in the Z direction. The first cell sacrificial pillars CSP1 may have the shape of a cylinder, an elliptical cylinder, or a pillar filling a tapered hole. An elliptical cylinder, for example, has an elliptical cross section in the XY plane. The first cell sacrificial pillars CSP1 may include a carbon layer. For example, the first cell sacrificial pillars CSP1 may include a carbon layer, may include a carbon layer and polysilicon, or may include a carbon layer and a metal nitride (e.g., TiN).

Subsequently, a second preliminary stack structure pSTK2 may be formed on the first preliminary stack structure pSTK1. The second preliminary stack structure pSTK2 may include alternately stacked second interlayer insulating layers IL2 and second sacrificial layers SF2. The second interlayer insulating layers IL2 and the second sacrificial layers SF2 may be stacked on each other in the Z direction. The lowermost second sacrificial layer among the second sacrificial layers SF2 may be in contact with the uppermost first interlayer insulating layer among the first interlayer insulating layers IL1.

The second interlayer insulating layers IL2 may include an insulating material. For example, the second interlayer insulating layers IL2 may include oxide layers (e.g., silicon oxide layers). The second interlayer insulating layers IL2 may include the same material as the first interlayer insulating layers IL1. The second sacrificial layers SF2 may include a material which may be selectively removed in a subsequent process. The second sacrificial layers SF2 may include a material having an etch selectivity different from that of the second interlayer insulating layers IL2. For example, the second sacrificial layers SF2 may include nitride layers.

Subsequently, second cell sacrificial pillars CSP2 may be formed through the second preliminary stack structure pSTK2. The second cell sacrificial pillars CSP2 may be formed in the cell region CR. Each of the second cell sacrificial pillars CSP2 may extend in the Z direction. The second cell sacrificial pillars CSP2 may overlap the first cell sacrificial pillars CSP1, respectively. A lower surface of each of the second cell sacrificial pillars CSP2 may be in contact with a corresponding upper surface of the first cell sacrificial pillars CSP1. The second cell sacrificial pillars CSP2 may have the shape of a cylinder, an elliptical cylinder, or a pillar filling a tapered hole. Because the second cell sacrificial pillars CSP2 are formed on the first cell sacrificial pillars CSP1, which have already been formed, irregularities may be formed on side surfaces of the first and second cell sacrificial pillars CSP1 and CSP2 at the interface between the first and second preliminary stack structures pSTK1 and pSTK2. For example, the width of an upper end of each of the first cell sacrificial pillars CSP1 may be greater than the width of a lower end of each of the second cell sacrificial pillars CSP2.

In addition, first sacrificial pillars SFP1 may be formed through the second preliminary stack structure pSTK2. The first sacrificial pillars SFP1 may be formed in the contact region CTR. For example, a portion of the second preliminary stack structure pSTK2 may be etched in the contact region CTR and a sacrificial material may be filled therein to form the first sacrificial pillars SFP1. Each of the first sacrificial pillars SFP1 may extend in the Z direction. A lower surface of each of the first sacrificial pillars SFP1 may be in contact with an upper surface of the first preliminary stack structure pSTK1. The first sacrificial pillars SFP1 may have the shape of a cylinder, an elliptical cylinder, or a pillar filling a tapered hole.

The second cell sacrificial pillars CSP2 and the first sacrificial pillars SFP1 may include a carbon layer. For example, the second cell sacrificial pillars CSP2 and the first sacrificial pillars SFP1 may include a carbon layer, may include a carbon layer and polysilicon, or may include a carbon layer and a metal nitride (e.g., TiN).

The first sacrificial pillars SFP1 may be formed simultaneously with the second cell sacrificial pillars CSP2. For example, the second preliminary stack structure pSTK2 may be etched to form openings in which a sacrificial material may be filled. The sacrificial material filled in the openings formed in the cell region CR may be the second cell sacrificial pillars CSP2, and the sacrificial material filled in the openings formed in the contact region CTR may be the first sacrificial pillars SFP1.

The first sacrificial pillars SFP1 may have a width corresponding to the width of the second cell sacrificial pillars CSP2. For example, the first sacrificial pillars SFP1 may have a width substantially equal to the width of the second cell sacrificial pillars CSP2. Because the first sacrificial pillars SFP1 and the second cell sacrificial pillars CSP2 are formed together by a process of etching the second preliminary stack structure pSTK2, the first sacrificial pillars SFP1 and the second cell sacrificial pillars CSP2 may be formed to have the same width as each other. For another example, the first sacrificial pillars SFP1 may have greater widths than the second cell sacrificial pillars CSP2. The width of the first sacrificial pillars SFP1 divided by the width of the second cell sacrificial pillars CSP2, for example, may be defined by a predetermined ratio. The width of the first sacrificial pillars SFP1 may be determined to be within a range in which the first sacrificial pillars SFP1 may be formed together with the second cell sacrificial pillars CSP2 by a single process of etching the second preliminary stack structure pSTK2.

When comparing the widths of a plurality of components in the present disclosure, it may be a comparison of the widths of respective components at a specific level. For example, it may be interpreted that the widths of the second cell sacrificial pillars CSP2 and the first sacrificial pillars SFP1 may be compared at a level corresponding to one of the second interlayer insulating layers IL2.

Subsequently, a third preliminary stack structure pSTK3 in which the third interlayer insulating layers IL3 and third sacrificial layers SF3 are alternately stacked may be formed. Subsequently, third cell sacrificial pillars CSP3 may be formed through the third preliminary stack structure pSTK3 in the cell region CR. The third cell sacrificial pillars CSP3 may respectively overlap the second cell sacrificial pillars CSP2 and may respectively overlap the first cell sacrificial pillars CSP1. In addition, second sacrificial pillars SFP2 may be formed through the third preliminary stack structure pSTK3 in the contact region CTR. One or more of the second sacrificial pillars SFP2 may overlap the first sacrificial pillars SFP1, and the remaining second sacrificial pillars SFP2 might not overlap any first sacrificial pillars SFP1.

The third cell sacrificial pillars CSP3 and the second sacrificial pillars SFP2 may include a carbon layer. For example, the third cell sacrificial pillars CSP3 and the second sacrificial pillars SFP2 may include a carbon layer, may include a carbon layer and polysilicon, or may include a carbon layer and a metal nitride (e.g., TiN).

The second sacrificial pillars SFP2 may be formed simultaneously with the third cell sacrificial pillars CSP3. For example, the third preliminary stack structure pSTK3 may be etched to form openings inside which sacrificial material may be filled. The sacrificial material filled in the openings formed in the cell region CR may be third cell sacrificial pillars CSP3, and the sacrificial substance filled in the opening formed in the contact region CTR may be second sacrificial pillars SFP2.

The second sacrificial pillars SFP2 may have a width corresponding to the width of the third cell sacrificial pillars CSP3. For example, the second sacrificial pillars SFP2 may have a width substantially equal to the width of the third cell sacrificial pillars CSP3. Because the second sacrificial pillars SFP2 and the third cell sacrificial pillars CSP3 are formed together by a process of etching the third preliminary stack structure pSTK3, the second sacrificial pillars SFP2 and the third cell sacrificial pillars CSP3 may be formed to have the same width as each other. For another example, the second sacrificial pillars SFP2 may have a greater width than the third cell sacrificial pillars CSP3. The width of the second sacrificial pillars SFP2 divided by the width of the third cell sacrificial pillars CSP3, for example, may be defined by a predetermined ratio. The width of the second sacrificial pillars SFP2 may be determined to be within a range in which the second sacrificial pillars SFP2 may be formed together with the third cell sacrificial pillars CSP3 by a single process of etching the third preliminary stack structure pSTK3.

Although not shown, pads may be formed at lower portions of the first sacrificial pillars SFP1 and at lower portions of the second sacrificial pillars SFP2 that do not overlap any first sacrificial pillars SFP1. For example, the pads may be formed by etching a portion of an upper end of the first preliminary stack structure pSTK1 and filling a carbon layer or a conductive layer (e.g., W). The pads formed in the first preliminary stack structure pSTK1 may be overlapped by the first sacrificial pillars SFP1.

In the present disclosure, the first to third preliminary stack structures pSTK1 to pSTK3 may be referred to as first to third sub-stack structures, respectively, and the entire structure including the first to third preliminary stack structures pSTK1 to pSTK3 may be referred to as a stack structure.

Referring to FIG. 4B, a first upper insulating layer UIL1 and a second upper insulating layer UIL2 may be formed over the third preliminary stack structure pSTK3. The first upper insulating layer UIL1 may be in contact with an upper surface of the third preliminary stack structure pSTK3. The first upper insulating layer UIL1 may cover the first to third cell sacrificial pillars CSP1 to CSP3 and the first and second sacrificial pillars SFP1 and SFP2. The first upper insulating layer UIL1 may include an oxide layer. The second upper insulating layer UIL2 may be formed on the first upper insulating layer UIL1. The second upper insulating layer UIL2 may cover the first upper insulating layer UIL1. The second upper insulating layer UIL2 may include a nitride layer.

Subsequently, portions of the first and second upper insulating layers UIL1 and UIL2 may be removed to expose the third cell sacrificial pillars CSP3. For example, holes exposing the third cell sacrificial pillars CSP3 may be formed through the first and second upper insulating layers UIL1 and UIL2.

Subsequently, the first to third cell sacrificial pillars CSP1 to CSP3 may be removed. Through the above-described holes, the third cell sacrificial pillars CSP3, the second cell sacrificial pillars CSP2, and the first cell sacrificial pillars CSP1 may be sequentially removed. The first to third cell sacrificial pillars CSP1 to CSP3 may be removed to form cell openings COP. Each of the cell openings COP may extend in the Z direction. Each of the cell openings COP may penetrate through the first to third preliminary stack structures pSTK1 to pSTK3.

Referring to FIG. 4C, the cell plugs CPL may be formed in the cell openings COP, respectively. For example, the memory layer ML, the channel layer CH, and the core pillar CO may be sequentially formed on side surfaces of the first to third preliminary stack structures pSTK1 to pSTK3 exposed through the cell openings COP. Subsequently, the capping layer CAP connected to the channel layer CH may be formed on the core pillar CO.

Subsequently, the second upper insulating layer UIL2 of FIG. 4B may be removed. As the second upper insulating layer UIL2 is removed, upper portions of the cell plugs CPL may extend farther in the Z direction than the first upper insulating layer UIL1, and thus, the upper portions of the cell plugs CPL may protrude from an upper surface of the first upper insulating layer UIL1.

Subsequently, a third upper insulating layer UIL3 may be formed on the first upper insulating layer UIL1. The third upper insulating layer UIL3 may cover the upper portions of the cell plugs CPL. The third upper insulating layer UIL3 may surround the upper portion of each of the cell plugs CPL protruding farther in the Z direction than the first upper insulating layer UIL1. The third upper insulating layer UIL3 may include an oxide layer.

Subsequently, a first hard mask HM1, a fourth upper insulating layer UIL4, and a second hard mask HM2 may be sequentially formed over the third upper insulating layer UIL3. The first hard mask HM1, the fourth upper insulating layer UIL4, and the second hard mask HM2 may cover the first to third preliminary stack structures pSTK1 to pSTK3. For example, the first hard mask HM1, the fourth upper insulating layer UIL4, and the second hard mask HM2 may cover the cell plugs CPL and the first and second sacrificial pillars SFP1 and SFP2. The first hard mask HM1 may include polysilicon. The fourth upper insulating layer UIL4 may include an oxide layer. The second hard mask HM2 may include a carbon layer. The thicknesses of each of the first hard mask HM1 and the second hard mask HM2 may be greater than the thickness of the fourth upper insulating layer UIL4.

Referring to FIG. 4D, first to third mask openings MO1 to MO3 penetrating through the second hard mask HM2, the fourth upper insulating layer UIL4, and the first hard mask HM1 may be formed. The first mask openings MO1 may overlap the first and second sacrificial pillars SFP1 and SFP2. The second mask openings MO2 may overlap the second sacrificial pillars SFP2. The third mask openings MO3 might not overlap either the first or the second sacrificial pillars SFP1 and SFP2. Subsequently, the second hard mask HM2 may be removed.

Subsequently, the first and third upper insulating layers UIL1 and UIL3 may be etched through the first to third mask openings MO1 to MO3. As the first and third upper insulating layers UIL1 and UIL3 are etched, the second sacrificial pillars SFP2 may be exposed through the first and second mask openings MO1 and MO2.

While the first and third upper insulating layers UIL1 and UIL3 are etched through the third mask openings MO3, the uppermost third interlayer insulating layer IL3 among the third interlayer insulating layers IL3 may be etched together. Spaces from which the third upper insulating layer UIL3, the first upper insulating layer UIL1, and the third interlayer insulating layer IL3 are etched through the third mask openings MO3 may be referred to as third preliminary openings POP3. The third preliminary openings POP3 may penetrate through the third upper insulating layer UIL3, the first upper insulating layer UIL1, and the uppermost third interlayer insulating layer IL3 among the third interlayer insulating layers IL3. Through the third preliminary openings POP3, the uppermost third sacrificial layer SF3 of the third sacrificial layers SF3 may be exposed.

Subsequently, the first and second sacrificial pillars SFP1 and SFP2 may be removed. The second sacrificial pillars SFP2 and the first sacrificial pillars SFP1 exposed through the first and second mask openings MO1 and MO2 may be etched. For example, the second sacrificial pillars SFP2 may be removed through the second mask openings MO2 to form second preliminary openings POP2. The second preliminary openings POP2 may penetrate through the third preliminary stack structure pSTK3. The upper surface of the second preliminary stack structure pSTK2 may be exposed through the second preliminary openings POP2. The second sacrificial pillars SFP2 may also be removed through the first mask openings MO1 to expose the first sacrificial pillars SFP1. The first sacrificial pillars SFP1 may also be removed through the first mask openings MO1. Spaces from which the first and second sacrificial pillars SFP1 and SFP2 are removed may be referred to as first preliminary openings POP1. The first preliminary openings POP1 may penetrate through the second and third preliminary stack structures pSTK2 and pSTK3. The upper surface of the first preliminary stack structure pSTK1 may be exposed through the first preliminary openings POP1.

The width of each of the first to third preliminary openings POP1 to POP3 may correspond to the width of the cell plug CPL (or each of the cell openings COP in FIG. 4B). For example, each of the first to third preliminary openings POP1 to POP3 may have a width substantially equal to the width of each of the cell plugs CPL. Because each of the first and second sacrificial pillars SFP1 and SFP2 has a width equal to the width of each of the first to third cell sacrificial pillars CSP1 to CSP3, each of the first to third preliminary openings POP1 to POP3 may also have a width equal to the width of each of the cell plugs CPL. For another example, each of the first to third preliminary openings POP1 to POP3 may have a greater width than the width of each of the cell plugs CPL. The width each of the first to third preliminary openings POP1 to POP3 divided by the width of each of the cell plugs CPL, for example, may be defined by a predetermined ratio.

Referring to FIG. 4E, a portion of the first hard mask HM1 exposed through the first to third mask openings MO1 to MO3 may be etched. As the portion of the first hard mask HM1 is etched, first to third mask openings MO1′ to MO3′ may be formed which are expanded relative to the first to third mask openings MO1 to MO3.

Referring to FIG. 4F, the second and third interlayer insulating layers IL2 and IL3 and the first and third upper insulating layers UIL1 and UIL3 may be etched through the first to third preliminary openings POP1 to POP3. For example, side surfaces of the second and third interlayer insulating layers IL2 and IL3 and the first and third upper insulating layers UIL1 and UIL3 may be exposed through the first to third preliminary openings POP1 to POP3. The second and third interlayer insulating layers IL2 and IL3 and the first and third upper insulating layers UIL1 and UIL3 which are exposed may be etched through the first to third preliminary openings POP1 to POP3. The areas from which the interlayer insulating layers IL2 and IL3 are etched leaves the recesses RC. The recesses RC may extend from the first to third preliminary openings POP1 to POP3. The recesses RC may project outwards relative to side surfaces of the first to third preliminary openings POP1 to POP3. The recesses RC may have a ring shape surrounding the first to third preliminary openings POP1 to POP3.

For example, portions of the second and third interlayer insulating layers IL2 and IL3 and portions of the first and third upper insulating layers UIL1 and UIL3 may be removed through the first preliminary openings POP1. Also, a portion of the third interlayer insulating layers IL3 and a portion of the first and third upper insulating layers UIL1 and UIL3 may be removed through the second preliminary openings POP2. With the recesses RC formed as the second and third interlayer insulating layers IL2 and IL3 are etched, the side surfaces of the first and second preliminary openings POP1 and POP2 may include a concavo-convex structure. In addition, portions of the first and third upper insulating layers UIL1 and UIL3 may be removed through the third preliminary openings POP3.

An isotropic wet etching process may be performed to selectively etch the second and third interlayer insulating layers IL2 and IL3 and the first and third upper insulating layers UIL1 and UIL3 including an oxide. Because the fourth upper insulating layer UIL4 includes an oxide, the fourth upper insulating layer UIL4 may also be removed while the second and third interlayer insulating layers IL2 and IL3 and the first and third upper insulating layers UIL1 and UIL3 are etched.

Referring to FIG. 4G, the second and third sacrificial layers SF2 and SF3 may be etched through the first to third preliminary openings POP1 to POP3 and the recesses RC. For example, portions of the second and third sacrificial layers SF2 and SF3 exposed through the first preliminary openings POP1 and the recesses RC extending from the first preliminary openings POP1 may be removed. In addition, portions of the third sacrificial layers SF3 exposed through the second preliminary openings POP2 and the recesses RC extending from the second preliminary openings POP2 may be removed. A portion of the uppermost third sacrificial layer SF3 exposed through the third preliminary openings POP3 may also be removed.

As the second and third sacrificial layers SF2 and SF3 are etched, the first to third preliminary openings POP1 to POP3 may become first to third expanded openings EOP1 to EOP3, respectively. The first to third expanded openings EOP1 to EOP3 may include spaces corresponding to the first to third preliminary openings POP1 to POP3, respectively. The first to third expanded openings EOP1 to EOP3 may each have a greater width than each of the first to third preliminary openings POP1 to POP3.

Each of the first to third expanded openings EOP1 to EOP3 may have a greater width than each of the cell plugs CPL. Because the first to third expanded openings EOP1 to EOP3 have greater widths than the first to third preliminary openings POP1 to POP3, the first to third expanded openings EOP1 to EOP3 may also have greater widths compared to the cell plugs CPL. In the present disclosure, the width may mean the length in the X direction and the length in the Y direction, or simply the diameter in the XY plane. That is, the first to third expanded openings EOP1 to EOP3 may have greater diameters than the cell plugs CPL at respective levels. For example, at a level corresponding to one of the third sacrificial layers SF3, the width of each of the first expanded openings EOP1 in the X direction may be greater than the width of each of the cell plugs CPL in the X direction.

The side surfaces of the first to third preliminary stack structures pSTK1 to pSTK3 exposed through the first to third expanded openings EOP1 to EOP3 may have irregularities. Because the interlayer insulating layers (e.g., IL2 and IL3) and the sacrificial layers (e.g., SF2 and SF3) are separately etched through the first to third preliminary openings POP1 to POP3, the side surfaces might not have a smooth curved shape. In another embodiment, unlike the embodiment shown in FIG. 4G, the side surfaces of the first to third preliminary stack structures pSTK1 to pSTK3 exposed through the first to third expanded openings EOP1 to EOP3 may have a smooth curved shape without irregularities.

Referring to FIG. 4H, one or more of the first to third expanded openings EOP1 to EOP3 may extend downward. The others of the first to third expanded openings EOP1 to EOP3 might not extend downward. For example, a first contact opening COP1 may be the same as the first expanded opening EOP1, a second contact opening COP2 may be the same as the second expanded opening EOP2, and a third contact opening COP3 may be the same as the third expanded opening EOP3. The first contact opening COP1 may expose the uppermost first interlayer insulating layer IL1 among the first interlayer insulating layers IL1. The second contact opening COP2 may expose the uppermost second interlayer insulating layer IL2 among the second interlayer insulating layers IL2. The third contact opening COP3 may expose the second third interlayer insulating layer IL3 from the top of the third interlayer insulating layers IL3.

Portions of the first to third preliminary stack structures pSTK1 to pSTK3 may be removed through one or more of the first to third expanded openings EOP1 to EOP3. For example, at least one first interlayer insulating layer IL1 and at least one first sacrificial layer SF1 may be etched through at least one of the first expanded openings EOP1. The first interlayer insulating layer IL1 and the first sacrificial layer SF1 may be etched to form a fourth contact opening COP4 having a greater length in the Z direction than the first expanded opening EOP1. The fourth contact opening COP4 may expose the second first interlayer insulating layer IL1 from the top of the first interlayer insulating layers IL1. In addition, at least one second interlayer insulating layer IL2 and at least one second sacrificial layer SF2 may be etched through at least one of the second expanded openings EOP2. The second interlayer insulating layer IL2 and the second sacrificial layer SF2 may be etched to form a fifth contact opening COP5 having a greater length in the Z direction than the second expanded opening EOP2. The fifth contact opening COP5 may expose the second second interlayer insulating layer IL2 from the top of the second interlayer insulating layers IL2. Furthermore, at least one third interlayer insulating layer IL3 and at least one third sacrificial layer SF3 may be etched through at least one of the third expanded openings EOP3. The third interlayer insulating layer IL3 and the third sacrificial layer SF3 may be etched to form a sixth contact opening COP6 having a greater length in the Z direction than the third expanded opening EOP3. The sixth contact opening COP6 may expose the third third interlayer insulating layer IL3 from the top of the third interlayer insulating layers IL3.

Processes may be performed to alternately remove interlayer insulating layers (e.g., IL1, IL2, and IL3) and sacrificial layers (e.g., SF1, SF2, and SF3) to form the fourth to sixth contact openings COP4 to COP6. Processes of sequentially etching an oxide layer and a nitride layer may be performed so that the fourth to sixth contact openings COP4 to COP6 have specific depths. However, the contact openings shown in FIG. 4H do not necessarily represent all the contact openings. Only some of the contact openings are shown for convenience of description, and contact openings corresponding to respective interlayer insulating layers (e.g., IL1, IL2, and IL3) may be formed. For example, contact openings corresponding to the respective interlayer insulating layers (e.g., IL1, IL2, and IL3) may be formed by adjusting the number of layers of the interlayer insulating layers (e.g., IL1, IL2, and IL3) and the sacrificial layers (e.g., SF1, SF2, and SF3) removed through the first to third expanded openings EOP1 to EOP3.

According to the present disclosure, because the first to third expanded openings EOP1 to EOP3 have greater widths than the first to third preliminary openings POP1 to POP3, the interlayer insulating layers (e.g., IL1, IL2, and IL3) and the sacrificial layers (e.g., SF1, SF2, and SF3) located below the first to third expanded openings EOP1 to EOP3 may be etched alternately. For example, in the case where the interlayer insulating layers (e.g., IL1, IL2, and IL3) and the sacrificial layers (e.g., SF1, SF2, and SF3) are etched without expanding the widths of the first to third preliminary openings POP1 to POP3, the interlayer insulating layers (e.g., IL1, IL2, and IL3) and the sacrificial layers (e.g., SF1, SF2, and SF3) might not be sufficiently removed. When the interlayer insulating layers (e.g., IL1, IL2, and IL3) and the sacrificial layers (e.g., SF1, SF2, and SF3) are not sufficiently removed, word line contacts formed in a subsequent process might not be in contact with respective word lines. However, for some embodiments of the present disclosure, because the interlayer insulating layers (e.g., IL1, IL2, and IL3) and the sacrificial layers (e.g., SF1, SF2, and SF3) are alternately etched through the first to third expanded openings EOP1 to EOP3, the first to sixth contact openings COP1 to COP6 may be formed having appropriate depths. This enables the word line contacts to be formed in a subsequent process to be in contact with respective word lines.

Referring to FIG. 4I, the first hard mask HM1 may be removed. Subsequently, spacer layers SPL may be formed on inner surfaces of the first to sixth contact openings COP1 to COP6. A spacer layer SPL may extend over side and bottom surfaces of each of the first to sixth contact openings COP1 to COP6. The spacer layers SPL may be formed on surfaces of the first to third preliminary stack structures pSTK1 to pSTK3 exposed through the first to sixth contact openings COP1 to COP6. The spacer layers SPL may be formed to conform to the shape of the inner surfaces of the first to sixth contact openings COP1 to COP6. Because the side surfaces of the first to sixth contact openings COP1 to COP6 are formed in a concavo-convex structure, the spacer layers SPL may also include such irregularities, rather than being flat or having continuous curvature. The spacer layers SPL may include an insulating material. For example, the spacer layers SPL may be oxide layers.

Subsequently, sacrificial filling layers SFL may be formed in the first to sixth contact openings COP1 to COP6. The sacrificial filling layers SFL may fill the first to sixth contact openings COP1 to COP6, respectively. The sacrificial filling layers SFL may be surrounded by the spacer layers SPL, respectively. The sacrificial filling layers SFL may be separated from the first to third preliminary stack structures pSTK1 to pSTK3 by the spacer layers SPL. The sacrificial filling layers SFL may include a conductive layer (e.g. a tungsten layer) or a carbon layer.

Referring to FIG. 4J, a fifth upper insulating layer UIL5 may be formed on the first to third preliminary stack structures pSTK1 to pSTK3. The fifth upper insulating layer UIL5 may be in contact with an upper surface of the third upper insulating layer UIL3. The fifth upper insulating layer UIL5 may cover the spacer layers SPL and the sacrificial filling layers SFL formed in the first to sixth contact openings COP1 to COP6.

Subsequently, the first sacrificial layers SF1 may be replaced with the first conductive layers CD1, the second sacrificial layers SF2 may be replaced with the second conductive layers CD2, and the third sacrificial layers SF3 may be replaced with the third conductive layers CD3. For example, the first to third sacrificial layers SF1 to SF3 may be removed, and the resulting spaces between the first to third interlayer insulating layers IL1 to IL3 may be filled with a conductive material. The first to third conductive layers CD1 to CD3 may be formed at the same time. The first to third conductive layers CD1 to CD3 may include the same material or materials equivalent to each other. The first conductive layers CD1 and the first interlayer insulating layers IL1 may constitute the first stack structure STK1. The second conductive layers CD2 and the second interlayer insulating layers IL2 may constitute the second stack structure STK2. The third conductive layers CD3 and the third interlayer insulating layers IL3 may constitute the third stack structure STK3.

Referring to FIG. 4K, the sacrificial filling layers SFL filled in the first to sixth contact openings COP1 to COP6 may be removed. Subsequently, a lower end of each of the spacer layers SPL may be removed. The lower end of each of the spacer layers SPL may be removed to leave the spacers SP. Because the lower end of each of the spacer layers SPL is removed, the first to third interlayer insulating layers IL1 to IL3 exposed through the first to sixth contact openings COP1 to COP6 may be etched. As portions of the first to third interlayer insulating layers IL1 to IL3 are removed, the first to sixth contact openings COP1 to COP6 may be extended downward. Each of the first to third conductive layers CD1 to CD3 may thus be exposed through the extended first to sixth contact openings COP1 to COP6. The spacers SP may extend on inner surfaces of the first to sixth contact openings COP1 to COP6.

Referring to FIG. 4L, the contacts CT may be formed which fill the first to sixth extended contact openings COP1 to COP6, respectively. Each of the contacts CT may be in contact with the first to third conductive layers CD1 to CD3. Each of the contacts CT may be electrically connected to the first to third conductive layers CD1 to CD3. The contacts CT may be surrounded by the spacers SP, respectively. Accordingly, the contacts CT may each be connected to one conductive layer while being insulated from the other conductive layers by the spacers SP.

Although not shown in FIGS. 4A to 4L, an additional opening exposing the uppermost third conductive layer CD3 among the third conductive layers CD3 may be formed, and a contact filling the additional opening may be formed.

Although FIGS. 3B and 4A to 4L illustrate embodiments in which a memory device includes three stack structures STK1 to STK3, the present disclosure is not limited thereto. For example, even when the memory device includes only two stack structures or includes four or more stack structures, the memory device may be included in the scope of the present disclosure as long as contact openings (e.g., COP1 to COP6) are formed by using expanded openings (e.g., EOP1 to EOP3) which are formed by widening widths, which correspond to the cell openings COP, of preliminary openings (e.g., POP1 to POP3).

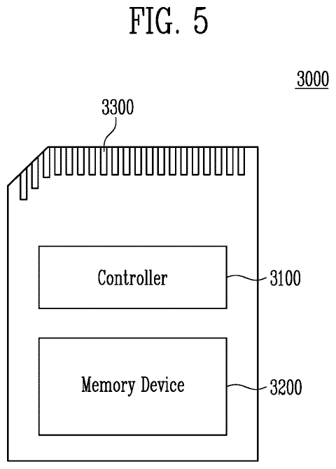

FIG. 5 is a diagram illustrating a memory card system 3000 to which a memory device 3200 of the present disclosure is applied.

Referring to FIG. 5, the memory card system 3000 includes a controller 3100, the memory device 3200, and a connector 3300.

The controller 3100 may be connected to the memory device 3200. The controller 3100 may be configured to access the memory device 3200. For example, the controller 3100 may be configured to control a program operation, a read operation, or an erase operation of the memory device 3200, or to control a background operation. The controller 3100 may be configured to provide an interface between the memory device 3200 and a host. The controller 3100 may be configured to run firmware to control the memory device 3200. For example, the controller 3100 may include components, such as Random-Access Memory (RAM), a processing unit, a host interface, a memory interface, and an error correction portion.

The controller 3100 may communicate with an external device through the connector 3300. The controller 3100 may communicate with the external device (e.g., a host) based on a specific communication protocol. For example, the controller 3100 is configured to communicate with the external device via at least one of various communication protocols, such as a Universal Serial Bus (USB), a multimedia card (MMC), an embedded MMC (eMMC), Peripheral Component Interconnect (PCI), PCI-express (PCI-E), Advanced Technology Attachment (ATA), Serial-ATA, Parallel-ATA, a Small Computer System Interface (SCSI), an Enhanced Small Disk Interface (ESDI), Integrated Drive Electronics (IDE), Firewire, Universal Flash Storage (UFS), WiFi, Bluetooth, or Non-Volatile Memory express (NVMe). For example, the connector 3300 may be defined by at least one of the various communication protocols described above.

The memory device 3200 may include a plurality of memory cells and may be configured in the same manner as the memory device 100 illustrated in FIG. 1.

The controller 3100 and the memory device 3200 may be integrated into one semiconductor device to form a memory card. For example, the controller 3100 and the memory device 3200 may be integrated into one semiconductor device to constitute a memory card such as a Personal Computer Memory Card International Association (PCMCIA), a Compact Flash (CF) card, a smart media card (SM, SMC), a memory stick, a multimedia card (MMC, RS-MMC, MMCmicro, eMMC), an SD card (SD, miniSD, microSD, SDHC), or Universal Flash Storage (UFS).

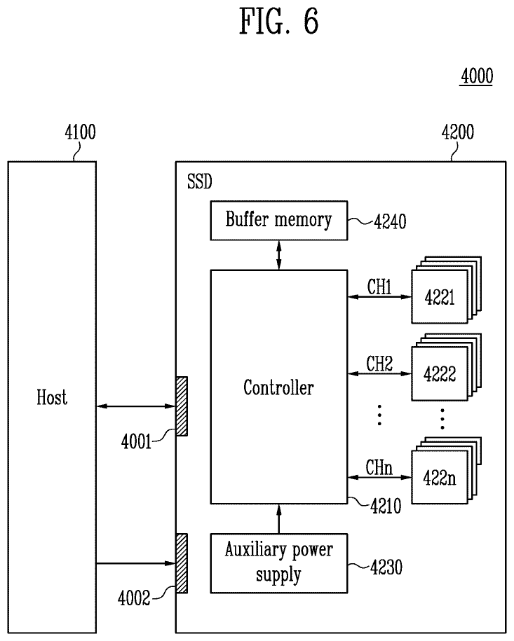

FIG. 6 is a diagram illustrating a Solid-State Drive (SSD) 4000 system to which a memory device of the present disclosure is applied.

Referring to FIG. 6, the SSD system 4000 may include a host 4100 and an SSD 4200. The SSD 4200 may exchange signals with the host 4100 through a signal connector 4001, and it may receive power through a power connector 4002. The SSD 4200 may include a controller 4210, a plurality of memory devices 4221 to 422n, an auxiliary power supply 4230, and buffer memory 4240.

The controller 4210 may control the plurality of memory devices 4221 to 422n in response to signals received from the host 4100. For example, the signals may be based on an interface of the host 4100 and the SSD 4200. For example, the signals may be defined by at least one of interfaces such as a Universal Serial Bus (USB), a multimedia card (MMC), an embedded MMC (eMMC), Peripheral Component Interconnect (PCI), PCI-express (PCI-E), Advanced Technology Attachment (ATA), Serial-ATA, Parallel-ATA, a Small Computer System Interface (SCSI), an Enhanced Small Disk Interface (ESDI), Integrated Drive Electronics (IDE), Firewire, Universal Flash Storage (UFS), WiFi, Bluetooth, or Non-Volatile Memory express (NVMe).

The plurality of memory devices 4221 to 422n may include a plurality of memory cells configured to store data. Each of the plurality of memory devices 4221 to 422n may be configured in the same manner as the memory device 100 illustrated in FIG. 1. The plurality of memory devices 4221 to 422n may communicate with the controller 4210 through channels CH1 to CHn.

The auxiliary power supply 4230 may be connected to the host 4100 through a power connector 4002. The auxiliary power supply 4230 may receive a power voltage from the host 4100 and may be charged. The auxiliary power supply 4230 may provide the power voltage of the SSD 4200 when the power supply from the host 4100 is not smooth. For example, the auxiliary power supply 4230 may be located in the SSD 4200 or may be located outside the SSD 4200. For example, the auxiliary power supply 4230 may be located on a main board and may provide auxiliary power to the SSD 4200.

The buffer memory 4240 may operate as buffer memory of the SSD 4200. For example, the buffer memory 4240 may temporarily store data received from the host 4100 or data received from the plurality of memory devices 4221 to 422n, or it may temporarily store metadata (e.g., a mapping table) of the memory devices 4221 and 422n. The buffer memory 4240 may include volatile memory, such as DRAM, SDRAM, DDR SDRAM, or LPDDR SDRAM, or non-volatile memory, such as FRAM, ReRAM, STT-MRAM, or PRAM.

According to some embodiments of the present disclosure, a manufacturing process of a memory device may be improved by complementing an etching process of a contact opening.

What is claimed is:

1. A method of manufacturing a memory device, the method comprising:
forming a cell opening penetrating through a stack structure;
forming a cell plug in the cell opening;
forming a preliminary opening penetrating at least a portion of the stack structure;
expanding the preliminary opening to form an expanded opening having a greater width than the preliminary opening by removing a portion of the stack structure through the preliminary opening;
forming a contact opening by extending the expanded opening farther downward by removing a portion of the stack structure through the expanded opening; and
forming a contact in the contact opening.

2. The method of claim 1, further comprising, before forming the cell opening, forming the stack structure by alternately stacking sacrificial layers and interlayer insulating layers.

3. The method of claim 2, wherein forming the stack structure comprises:
forming a first sub-stack structure;
forming a first cell sacrificial pillar penetrating through the first sub-stack structure;
forming a second sub-stack structure on the first sub-stack structure; and
forming a second cell sacrificial pillar and a first sacrificial pillar which penetrate through the second sub-stack structure,
wherein the second cell sacrificial pillar overlaps the first cell sacrificial pillar.

4. The method of claim 3, wherein forming the cell opening comprises removing the first cell sacrificial pillar and the second cell sacrificial pillar.

5. The method of claim 3, wherein forming the preliminary opening comprises:
forming a hard mask covering the cell plug;
exposing the first sacrificial pillar by removing a portion of the hard mask; and
forming the preliminary opening by removing the first sacrificial pillar.

6. The method of claim 2, wherein forming the expanded opening comprises:
forming recesses extending from the preliminary opening by removing portions of the interlayer insulating layers exposed through the preliminary opening; and
forming the expanded opening by removing portions of the sacrificial layers exposed through the preliminary opening and the recesses.

7. The method of claim 6, wherein each of the recesses is formed to have a ring shape surrounding the preliminary opening.

8. The method of claim 2, wherein forming the contact opening comprises:
etching at least one of the interlayer insulating layers located below the expanded opening; and
etching at least one of the sacrificial layers located below the expanded opening.

9. The method of claim 1, wherein the preliminary opening is formed to have a width equal to or greater than the width of the cell opening by a predetermined ratio.

10. The method of claim 1, wherein the expanded opening is formed so that a side surface of the stack structure exposed through the expanded opening has irregularities.

11. The method of claim 1, further comprising, after forming the contact opening:
forming a spacer layer extending over an inner surface of the contact opening; and
forming a sacrificial filling layer filling in the contact opening.

12. The method of claim 11, wherein the stack structure includes sacrificial layers and interlayer insulating layers, the sacrificial layers being alternately stacked with the interlayer insulating layers, and
wherein the method further comprises, after forming the sacrificial filling layer:
replacing the sacrificial layers with conductive layers;
removing the sacrificial filling layer;
forming a spacer by removing a lower end of the spacer layer; and
exposing one of the conductive layers by etching one of the interlayer insulating layers through the contact opening.

13. The method of claim 12, wherein the contact is formed to be surrounded by the spacer and in contact with one of the conductive layers.

14. The method of claim 1, wherein forming the cell plug in the cell opening comprises:
forming a memory layer on a side surface of the stack structure exposed by the cell opening;
forming a channel layer on an inner surface of the memory layer; and
forming a core pillar filling in the channel layer.

15. The method of claim 14, wherein forming the memory layer comprises sequentially forming a blocking layer, a charge trap layer, and a tunneling layer on the side surface of the stack structure exposed by the cell opening.

16. The method of claim 14, further comprising, after forming the core pillar, forming a capping layer on the core pillar, the capping layer being connected to the channel layer.

17. The method of claim 1, wherein, in forming the cell plug in the cell opening, irregularities are formed on a side surface of the cell plug.

18. The method of claim 1, wherein the cell opening is formed to have a greater depth than the preliminary opening.

19. The method of claim 1, wherein the cell opening and the preliminary opening are formed to have the same width.

20. The method of claim 1, wherein the contact is formed to have a width greater than a width of the cell plug.
